(19) United States
(12) Patent Application Publication
(10) Pub. No.: US 2023/0350307 A1
(43) Pub. Date: Nov. 2, 2023

(54) OPTICAL ELEMENT FOR REFLECTING RADIATION, AND OPTICAL ASSEMBLY

(71) Applicant: Carl Zeiss SMT GmbH, Oberkochen (DE)

(72) Inventors: Stefan Xalter, Oberkochen (DE); Soeren Knorr, Aalen (DE)

(21) Appl. No.: 18/350,522

(22) Filed: Jul. 11, 2023

Related U.S. Application Data
(63) Continuation of application No. PCT/EP2021/084386, filed on Dec. 6, 2021.

(30) Foreign Application Priority Data
Feb. 24, 2021 (DE) 102021201715.0

(51) Int. Cl. G03F 7/00; G02B 5/08

(52) U.S. Cl. CPC G03F 7/70033; G02B 5/0891; G03F 7/70316; G03F 7/702

(57) ABSTRACT

An optical element for reflecting radiation comprises: a substrate having first and second partial bodies put together at an interface; a reflective coating applied to a surface of the first partial body; a plurality of cooling channels running in the substrate in the region of the interface below the surface to which the reflective coating; a distributor in the substrate for connecting a coolant inlet to the plurality of cooling channels; and a collector in the substrate for connecting the plurality of cooling channels to a coolant outlet. The distributor and/or the collector extend, proceeding from the interface, further into the second partial body of the substrate than into the first partial body of the substrate. An optical arrangement, for example in an EUV lithography system, comprises: at least one such optical element; and a cooling device designed for flowing a coolant through the plurality of cooling channels.

### CROSS-REFERENCE TO RELATED APPLICATIONS

The present application is a continuation of, and claims benefit under 35 USC 120 to, international application PCT/EP2021/084386, filed Dec. 6, 2021, which claims benefit under 35 USC 119 of German Application No. 10 2021 201 715.0 of Feb. 24, 2021. The entire disclosure of each these applications is incorporated by reference herein.

### FIELD

The disclosure relates to an optical element for reflecting radiation, such as for reflecting EUV radiation, comprising: a substrate, which has a first partial body and a second partial body that are put together at an interface, a reflective coating, which is applied to a surface of the first partial body, a plurality of cooling channels, which run in the substrate in a region of the interface below the surface to which the reflective coating is applied, a distributor, which is formed in the substrate for connecting a coolant inlet to the plurality of cooling channels, and a collector, which is formed in the substrate for connecting the plurality of cooling channels to a coolant outlet. The disclosure also relates to an optical arrangement, such as an EUV lithography system, which comprises at least one such optical element and a cooling device, which is designed for the flowing of a coolant through the plurality of cooling channels.

### BACKGROUND

Reflective optical elements for lithography, such as for EUV lithography, are subject to increasingly intense thermal loads on account of the rising power of the radiation sources used in the operation of these elements. This applies for example to the mirrors of projection systems for EUV lithography. For the substrate of reflective optical elements of this type, which are also referred to below as mirrors to simplify matters, attempts have been made to make use of a material having a coefficient of thermal expansion that is as close to “zero” as possible. In reality, the best-case scenario is that of satisfying this for a certain temperature, which is also referred to as zero crossing temperature.

The mirror in such a projection system can heat up differently generally depending on the different settings or illumination states, with the result that the mirror can only ever be operated in the vicinity of the zero crossing temperature. This can lead to the mirror, more precisely the surface with the reflective coating, deforming under the thermal load during the irradiation. With increasing thermal load, this “mirror heating” problem can have a limiting effect on the performance of the optical arrangement in which the mirror is arranged.

There are mechatronic approaches for addressing this issue. Another, comparatively simple concept involves directly cooling a respective mirror, that is to say have a cooling fluid flow through the substrate of the mirror, more precisely in the cooling channels formed on the substrate. A feature of this concept is that it is possible to set the temperature of the mirror comparatively precisely by way of the temperature of the cooling fluid, that is to say the mirror has a thermal reference.

For the direct cooling of a mirror in an optical arrangement, for example in an EUV lithography apparatus, a multiplicity of boundary conditions, for which an optimized balance is to be found, typically apply. It has been shown that it can be favorable if a plurality of generally parallel cooling channels, which run below the surface to which the reflective coating is applied, is formed in the substrate. To have sufficient play for the geometric design, the channel geometries of these cooling channels can be formed in two or more partial bodies of the substrate, which are connected to one another by a suitable bonding method or optionally by optical contact bonding at one or more interfaces. It can be desirable for there to be relatively few interfaces in the substrate.

A distributor for connecting a coolant inlet of the substrate to the plurality of cooling channels and a collector for connecting the plurality of cooling channels of the substrate to a coolant outlet can be used to achieve relatively few direct connections on the substrate of the mirror.

DE 10 2019 217 530 A1 has disclosed an optical element in the form of a mirror which has a first layer made of a first material and a second layer made of a second material, which are put together along an interface. The optical element also has a cooling device which runs in the region of the interface and is configured to cool the optical element. The cooling device may have multiple cooling channels, through which a coolant, for example cooling water, is able to flow. The cooling channels may extend parallel to one another and laterally open into side channels which are connected to a coolant inlet or to a coolant outlet.

Internal pressure can arise in the cooling channels and, for example, in the distributor or in the collector when a cooling fluid, such as a cooling liquid, flows through the cooling channels, the internal pressure possibly leading to unwanted deformations on the surface to which the reflective coating is applied.

### SUMMARY

The disclosure seeks to provide an optical element and an optical arrangement which make it possible to reduce deformations on the surface of the optical element to which the reflective coating is applied by virtue of direct cooling with a cooling fluid.

According to one aspect, the disclosure provides an optical element for reflecting radiation, such as for reflecting EUV radiation, comprising: a substrate, which has a first partial body and a second partial body that are put together at an interface, a reflective coating, which is applied to a surface of the first partial body, a plurality of cooling channels, which run in the substrate in a region of the interface below the surface to which the reflective coating is applied, a distributor, which is formed in the substrate for connecting a coolant inlet to the plurality of cooling channels, and a collector, which is formed in the substrate for connecting the plurality of cooling channels to a coolant outlet. The distributor and/or the collector, proceeding from the interface, extend further into the second partial body of the substrate than into the first partial body of the substrate.

The extension of the distributor/collector into the first partial body and into the second partial body relates to the thickness direction of the substrate. The extension of the distributor/collector into the first partial body is generally very small. The maximum spacing of the distributor/collector from the interface into the first partial body may for example not be greater than the maximum extension of a respective cooling channel into the first partial body. By contrast, the (maximum) extension of the distributor/collector into the second partial body is generally (considerably) greater than the maximum extension of a respective cooling channel into the second partial body. The extension of the distributor/collector into the second partial body may for example correspond to at least five times the extension of the distributor/collector into the first partial body. The distributor and/or the collector may optionally extend only into the second body—but not into the first body—proceeding from the interface.

By contrast with what is the case for the side channels described in DE 10 2019 217 530 A1, which run along the interface between the two partial bodies, in the case of this aspect of the disclosure the distributor and/or the collector are/is placed largely, if appropriate completely, in the second partial body, that is to say that, proceeding from the interface, the distributor/collector runs further inside the second partial body than inside the first partial body. In this case, the distributor/collector is connected to the cooling channels, which extend along the interface. In this way, it is possible to reduce the influence of deformations of the substrate on the shape of the surface of the first partial body in the region with the reflective coating, which are possibly caused by the internal pressure of the cooling fluid in the region of the distributor/collector.

The cross section of a respective cooling channel may be divided between the two partial bodies. In this case, a respective groove-shaped depression may be formed in the first partial body and a further groove-shaped depression may be formed in the second partial body, the two groove-shaped depressions being joined together to form a single cooling channel when the two partial bodies are connected along the interface, for example as described in DE 10 2019 217 530 A1. In this case, a respective groove-shaped depression is milled both into the first partial body and into the second partial body. However, it is also possible that a groove-shaped depression is milled only into the first partial body or only into the second partial body and the respective other partial body covers the depression in the manner of a lid in order to form the cross section of the cooling channel. In both cases, the interface can run within or on the edge of the cross section of a respective cooling channel, with the result that it could be enough to connect a respective cooling channel to the coolant inlet or to the coolant outlet when the distributor/collector, in the second partial body of the substrate, extends into the region of the interface. The distributor/collector may, however, also extend into the first partial body, for example in order to connect the cooling channels to one another in that part of their cross section that extends into the first partial body.

The distributor and the collector may have the same construction. In this case, the distributor can be distinguished from the collector on the optical element only when a cooling medium flows through the optical element and/or the cooling channels. However, it is also possible for the distributor and the collector to have different designs, that is to say have a different geometry, in order to optimize the flow of the cooling medium.

In an embodiment, the distributor and/or the collector, in the second partial body, if appropriate also in the first partial body, at least in a portion proceeding from the interface, are aligned at an angle of at most 30° in relation to a thickness direction of the substrate. In order to reduce the effects of the internal pressure in the distributor/collector on the surface with the reflective coating, it can be desirable to tilt the distributor/collector relative to the surface of the first partial body and/or relative to the interface at least in a portion proceeding from the interface. In this way, the surface area, which might bulge owing to the internal pressure of the cooling fluid, of the distributor/collector is also tilted relative to the surface, as a result of which the effect of the bulging on the geometry of the surface is reduced. The distributor/collector may, in the portion connected to the interface, extend for example in and/or parallel to the thickness direction of the substrate, that is to say perpendicularly to a generally planar basic area of the second partial body, but this is not mandatory.

In an embodiment, the distributor and/or the collector, in the second partial body, if appropriate also in the first partial body, at least in a portion proceeding from the interface, run below a partial region of the surface that is not covered by the reflective coating. In order to avoid large deformations in the region of the surface to which the reflective coating is applied, or in the optically utilized partial region of the reflective coating, it can be favorable to position the distributor/collector as far away from the optically utilized surface area as possible. In such an embodiment, it is typically desirable for the cooling channels to also extend into that partial region of the surface that is not covered by the reflective coating. In order to reduce the effects of the fluid pressure, it may also be possible for the distributor/collector to indeed extend into that partial region of the surface that is covered by the reflective coating, but not to extend into an optically utilized partial region of the reflective coating. Used radiation is applied to the optically utilized partial region when the optical element is irradiated in an optical arrangement, for example in an EUV lithography apparatus.

In an aspect of the disclosure, which for example can be combined with the aspect described above, the distributor has a distributor chamber which widens from the coolant inlet toward the interface, and/or the collector has a collecting chamber which tapers from the interface toward the coolant outlet.

In this aspect of the disclosure, the distributor/collector, more precisely the distributor chamber/collecting chamber, may also extend along the interface between the first and the second partial body without the distributor/collector extending further into the second partial body than into the first partial body. In this case, it can be favorable for the distributor chamber/collecting chamber to have a form which is as flat as possible along the interface. The widening or the tapering of the flow cross section of the respective chamber can realize a substantially triangular, or funnel-shaped, geometry of the distributor/collector that is optimized in terms of flow. However, this geometry also could lead to the surface area of the distributor/collector being comparatively large. This, and the fact that the interface and thus the distributor/collector generally run at a small spacing from the surface to which the reflective coating is applied, can lead to the internal pressure in the distributor chamber/collecting chamber possibly also leading to bulging of the surface.

For the case in which the distributor chamber/collecting chamber extends along the interface between the two partial bodies, it has therefore proven to be favorable if they run only below a partial region of the surface that is not covered by the reflective coating (see above).

In a refinement of this embodiment, the distributor chamber extends from the coolant inlet to the interface and/or the collecting chamber extends from the interface to the coolant outlet. For example, it can be favorable in this case if the distributor chamber/collecting chamber, proceeding from the interface, is aligned substantially perpendicularly to the thickness direction of the substrate, as was described above.

However, in this case the distributor chamber/collecting chamber still has large surface areas on which the internal pressure of the cooling fluid acts and which can thus lead to deformation on the surface. It therefore can be favorable if the distributor chamber/collecting chamber do not extend to the interface or are not directly connected to the interface, since the distributor chamber/collecting chamber have their greatest lateral extent there.

In an embodiment, the distributor and/or the collector have/has a portion which proceeds from the interface and has connecting channels for connecting at least one respective cooling channel to the coolant inlet or to the coolant outlet. In this embodiment, the cooling channels can be continued in connecting channels, which are connected to one or more of the cooling channels in the region of the interface.

The connecting channels may, in the portion proceeding from the interface, be aligned for example at an angle of no more than 30° relative to a thickness direction of the substrate. In this way, the cooling channels in the vicinity of the edge of the optically utilized partial region of the surface and/or in the vicinity of that partial region of the surface that is covered with a reflective coating are deflected substantially in the vertical direction. In this way, the cooling channels and/or the connecting channels can be distributed or converged in a further portion of the distributor/collector that is spaced apart from the surface of the substrate and/or from the interface in the thickness direction.

It is possible for a cooling channel to be assigned to exactly one connecting channel. In this case, the connecting channel can constitute a continuation of the cooling channel into the second partial body of the substrate. The connecting channels are typically bored into the second partial body of the substrate, that is to say the connecting channels are bores.

Generally, a number of cooling channels, for example, ten or more cooling channels, each of which has a comparatively small cross-sectional area, is formed in the substrate. When the connecting channels, which generally moreover have a comparatively great length, or depth, are being bored, there is therefore a manufacturing-related risk of the second partial body of the substrate being damaged during the boring operation.

In a refinement of the above-described embodiment, a respective connecting channel is connected to at least two, for example to exactly two, cooling channels. In this way, the cross-sectional area of the connecting channel directly adjacent to the cooling channel can be enlarged to at least twice the cross-sectional area, as a result of which the manufacturing risk when the connecting channels are being bored can be lowered.

In a further refinement, a cross section of a respective connecting channel decreases from the interface, for example in stages. For the case in which the spacings between adjacent connecting channels are comparatively small and the surface areas of the connecting channels to which fluid pressure is applied are comparatively large owing to the comparatively large cross section of the connecting channels, it may be favorable to vary the bore diameter of the connecting channels, for example to reduce it from the interface. The cross section of a respective connecting channel can be reduced for example in stages, that is to say the connecting channel can have one or possibly more stages in which the cross section of the connecting channel progressively decreases. It is also possible to vary or reduce the cross section of a respective connecting channel continuously.

In an embodiment, the distributor chamber is connected to that portion of the distributor that has the connecting channels of the distributor and/or the collecting chamber is connected to that portion of the collector that has the connecting channels of the collector. In this case, using the connecting channels, the distributor chamber/collecting chamber can be spaced apart from the surface with the reflective coating and/or from the interface between the two partial bodies in the thickness direction of the substrate. The greater spacing from the surface can cause deformations of the substrate that are caused by the bulging of the respective chamber owing to the pressure of the cooling fluid to have a less pronounced effect on the geometry of the surface than in the case described above, in which the distributor chamber/collecting chamber is directly connected to the interface.

In a refinement of this embodiment, the distributor chamber and/or the collecting chamber extend along a further interface between the second partial body and a third partial body of the substrate that is put together with the second partial body at the further interface. The further interface may for example extend substantially parallel to the interface at which the first partial body is put together with the second partial body. In this way, the distributor chamber and/or the collecting chamber can be offset from the interface to the further interface in the thickness direction of the substrate. The further interface is generally used since the distributor chamber and/or the collecting chamber cannot be readily realized only in the second partial body owing to the funnel-shaped geometry if the chamber is intended to be offset from the interface in the thickness direction.

In an embodiment, the connecting channels of the distributor open into a common inlet channel which is connected to the coolant inlet, and/or the connecting channels of the collector open into a common outlet channel which is connected to the coolant outlet. The inlet channel and/or the outlet channel are typically in the form of bores in the second partial body. The inlet channel and/or the outlet channel may for example run substantially parallel to the base area of the second partial body and/or of the substrate, but this is not mandatory. The inlet channel and/or the outlet channel may form a transverse bore in the second partial body, into which the connecting channels open. The coolant inlet and/or the coolant outlet may be in the form of openings at the free ends of the inlet channel and of the outlet channel, respectively.

In an embodiment, the coolant inlet and/or the coolant outlet are formed in the second partial body and/or in the third partial body of the substrate. The coolant inlet and/or the coolant outlet may for example form an opening in a side face of the second and/or of the third partial body, but it is also possible for the coolant inlet and/or the coolant outlet to be formed on the underside of the substrate, that is to say on the opposite surface of the substrate to the interface and/or the further interface. In the region of the coolant inlet and/or the coolant outlet, the substrate is typically shaped in such a way that a coolant line can be easily connected to the coolant inlet and/or to the coolant outlet.

In an embodiment, the cross section of a respective cooling channel of the plurality of cooling channels is divided between the first partial body and the second partial body. As was described above, it is possible to divide the cross-sectional area of the cooling channels or of one or more of the cooling channels between the two partial bodies. In this case, the cooling channel generally does not run in or parallel to the generally planar interface.

In an embodiment, the surface of the substrate to which the reflective coating is applied is curved and/or the cooling channel itself is curved (in the thickness direction of the substrate), with the curved cooling channel can have a constant spacing from the curved surface. In the case of a substrate of this type, the above-described division of the cross section of the cooling channel between the two partial bodies can be favorable for example for the case in which the interface itself does not follow the curvature of the surface and has a planar form, for example. In this case, the division of the cross section between the two partial bodies can help ensure that, in spite of the planar interface, the curved cooling channel follows the curved surface, with the result that the cooling channel runs at a constant spacing from the curved surface. In this case, a groove-shaped depression having a curvature that follows the curvature of the surface is introduced generally not only into the first partial body but also into the second partial body. In this case, the cooling channel can be formed by putting together a correspondingly curved groove-shaped depression in the first partial body and the groove-shaped depression in the second partial body along the interface. This can help make it possible to have the effect that the curved cooling channel has a channel cross section which is constant over its length.

A further aspect of the disclosure relates to an optical arrangement, for example an EUV lithography system, comprising: at least one optical element formed in the manner described above, and a cooling device which is designed for the flowing of a coolant through the plurality of cooling channels. The EUV lithography system can be an EUV lithography apparatus for exposing a wafer, or can be some other optical arrangement that uses EUV radiation, for example an EUV inspection system, for example for inspecting masks, wafers or the like that are used in EUV lithography. The reflective optical element may for example be a mirror of a projection system of an EUV lithography apparatus. By way of example, the cooling device may be designed to allow a coolant in the form of a cooling fluid, for example a cooling liquid, for example in the form of cooling water or the like, to flow through the cooling channels. For this purpose, the cooling device may optionally have a pump and also suitable supply and lead-away lines. The optical arrangement may also be a lithography system for another wavelength range, for example for the DUV wavelength range, for example a DUV lithography apparatus or an inspection system for inspecting masks, wafers or the like.

Further features the disclosure will become apparent from the following description of exemplary embodiments of the disclosure, with reference to the figures, and from the claims. The individual features may each be implemented alone or in a plurality in any combination in one variant of the disclosure.

### BRIEF DESCRIPTION OF THE DRAWINGS

Exemplary embodiments are depicted in the schematic drawings and are explained in the following description. In the figures:

FIG. 1 shows a schematic meridional section through a projection exposure apparatus for EUV projection lithography;

FIG. 2 shows a schematic illustration of a mirror having a plurality of cooling channels and a distributor chamber and a collecting chamber which run along an interface between two partial bodies of a substrate;

FIGS. 3A-3B show schematic illustrations of a mirror, in the case of which the distributor chamber and the collecting chamber are formed only in the second partial body and extend in the thickness direction of the substrate;

FIGS. 4A-4B show schematic illustrations of a mirror having a distributor chamber and a collecting chamber which run along a further interface between the second partial body and a third partial body of the substrate;

FIGS. 5A-5C show schematic illustrations of a mirror having connecting channels running in the thickness direction, in order to connect the cooling channels to an inlet channel of the distributor; and

FIGS. 6A-6B show schematic illustrations of a mirror, similar to FIGS. 5A-5C, which has a curved surface and in the case of which the cooling channels have a cross section which runs both in the first partial body and in the second partial body.

### DESCRIPTION OF EXEMPLARY EMBODIMENTS

In the following description of the drawings, identical reference signs are used for components that are the same or have the same function.

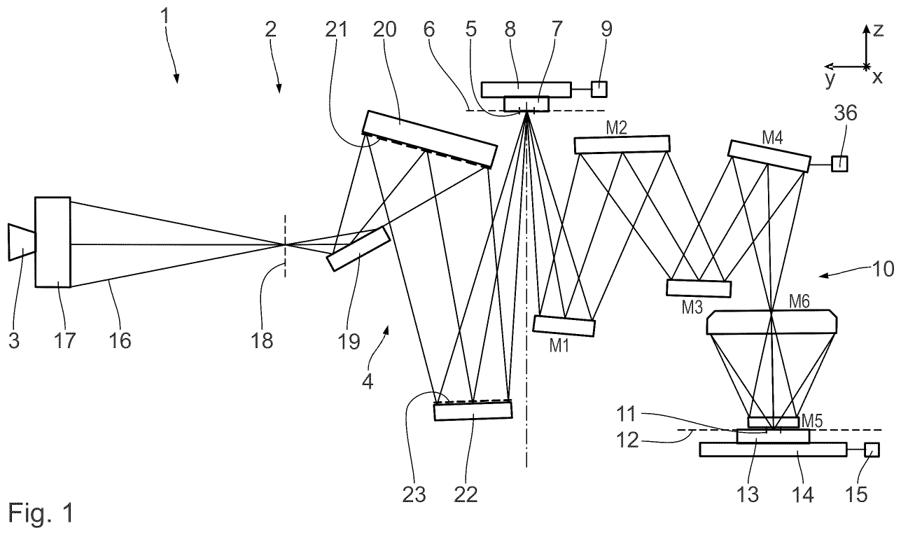

Certain components of an optical arrangement for EUV lithography in the form of a microlithographic projection exposure apparatus 1 are described by way of example below with reference to FIG. 1. The description of the basic construction of the projection exposure apparatus 1 and its components should not be understood as having a limiting effect in this case.

An embodiment of an illumination system 2 of the projection exposure apparatus 1 has, in addition to a light or radiation source 3, an illumination optical unit 4 for illuminating an object field 5 in an object plane 6. In an alternative embodiment, the light source 3 may also be provided as a module separate from the rest of the illumination system. In this case, the illumination system does not comprise the light source 3.

A reticle 7 arranged in the object field 5 is illuminated. The reticle 7 is held by a reticle holder 8. The reticle holder 8 is displaceable for example in a scanning direction by way of a reticle displacement drive 9.

An embodiment of an illumination system 2 of the projection exposure apparatus 1 has, in addition to a light or radiation source 3, an illumination optical unit 4 for illuminating an object field 5 in an object plane 6. In an alternative embodiment, the light source 3 may also be provided as a module separate from the rest of the illumination system. In this case, the illumination system does not comprise the light source 3.

For explanation purposes, a Cartesian xyz coordinate system is depicted in FIG. 1. The x direction runs perpendicularly to the plane of the drawing. The y direction runs horizontally, and the z direction runs vertically. The scanning direction runs in the y direction in FIG. 1. The z direction runs perpendicularly to the object plane 6.

The projection exposure apparatus 1 comprises a projection system 10. The projection system 10 serves for imaging the object field 5 into an image field 11 in an image plane 12. A structure on the reticle 7 is imaged onto a light-sensitive layer of a wafer 13 arranged in the region of the image field 11 in the image plane 12. The wafer 13 is held by a wafer holder 14. The wafer holder 14 is displaceable for example along the y direction by way of a wafer displacement drive 15. The displacement on the one hand of the reticle 7 by way of the reticle displacement drive 9 and on the other hand of the wafer 13 by way of the wafer displacement drive 15 may be synchronized with one another.

The radiation source 3 is an EUV radiation source. The radiation source 3 emits, for example, EUV radiation 16, which is also referred to below as used radiation, illumination radiation or illumination light. For example, the used radiation has a wavelength in the range between 5 nm and 30 nm. The radiation source 3 may be a plasma source, for example an LPP source (Laser Produced Plasma) or a GDPP source (Gas Discharge Produced Plasma). It may also be a synchrotron-based radiation source. The radiation source 3 may be a free electron laser (FEL).

The illumination radiation 16 emanating from the radiation source 3 is focused by a collector mirror 17. The collector mirror 17 may be a collector mirror with one or more ellipsoidal and/or hyperboloidal reflection surfaces. The illumination radiation 16 may be incident on at least one reflection surface of the collector mirror 17 with grazing incidence (GI), i.e. at angles of incidence of greater than 45°, or with normal incidence (NI), i.e. at angles of incidence of less than 45°. The collector mirror 17 may be structured and/or coated, firstly to optimize its reflectivity for the used radiation and secondly to suppress extraneous light.

The illumination radiation 16 propagates through an intermediate focus in an intermediate focal plane 18 downstream of the collector mirror 17. The intermediate focal plane 18 may constitute a separation between a radiation source module, having the radiation source 3 and the collector mirror 17, and the illumination optical unit 4.

The illumination optical unit 4 comprises a deflection mirror 19 and, arranged downstream thereof in the beam path, a first facet mirror 20. The deflection mirror 19 may be a plane deflection mirror or, alternatively, a mirror with a beam-influencing effect going beyond a pure deflection effect. As an alternative or in addition, the deflection mirror 19 may be in the form of a spectral filter that separates a used light wavelength of the illumination radiation 16 from stray light of a wavelength deviating therefrom. The first facet mirror 20 comprises a multiplicity of individual first facets 21, which are also referred to as field facets below. FIG. 1 depicts only some of the facets 21 by way of example. In the beam path of the illumination optical unit 4, a second facet mirror 22 is arranged downstream of the first facet mirror 20. The second facet mirror 22 comprises a plurality of second facets 23.

The illumination optical unit 4 consequently forms a doubly faceted system. This is also referred to as a fly's eye condenser (fly's eye integrator). The individual first facets 21 are imaged into the object field 5 with the aid of the second facet mirror 22. The second facet mirror 22 is the last beam-shaping mirror or indeed the last mirror for the illumination radiation 16 in the beam path upstream of the object field 5.

The projection system 10 comprises a plurality of mirrors Mi, which are consecutively numbered in accordance with their arrangement in the beam path of the projection exposure apparatus 1.

In the example depicted in FIG. 1, the projection system 10 comprises six mirrors M1 to M6. Alternatives with four, eight, ten, twelve or any other number of mirrors Mi are similarly possible. The penultimate mirror M5 and the last mirror M6 each have a passage opening for the illumination radiation 16. The projection system 10 is a doubly obscured optical unit. The projection system 10 has an image-side numerical aperture that is greater than 0.4 or 0.5 and can also be greater than 0.6, and can be for example 0.7 or 0.75.

Just like the mirrors of the illumination optical unit 4, the mirrors Mi can have a highly reflective coating for the illumination radiation 16.

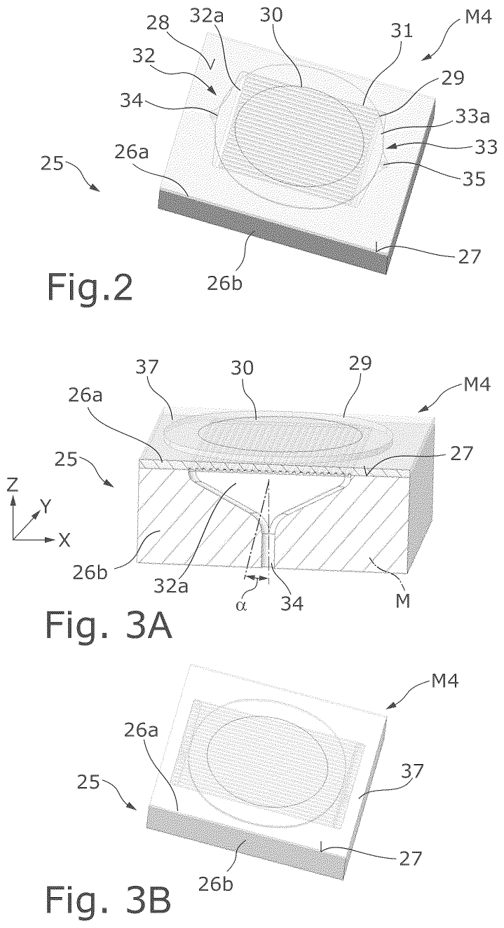

FIG. 2 shows, by way of example, a mirror M4 of the projection system 10, the mirror comprising a substrate 25 which is formed from a first partial body 26a and a second partial body 26b. The first partial body 26a, which is plate-shaped in the example shown, and the second partial body 26b, which forms a main body of the substrate 25, are put together or connected to one another at a common interface 27, which in the example shown is a planar surface, although this is not mandatory. The connection between the two partial bodies 26a, b is established by a conventional joining or bonding process, for example by high-temperature or low-temperature bonding or by optical contact bonding. The material of the first partial body 26a and of the second partial body 26b may be identical, but different materials may also be involved. In the example shown, both the material of the first partial body 26a and the material of the second partial body 26b are ultra low expansion glass (ULE®). The substrate 25, or the two partial bodies 26a, b, may also be made from another material which has as low as possible a coefficient of thermal expansion, for example a glass ceramic, for example Zerodur®.

A reflective coating 29 is applied to an exposed surface 28 of the first partial body 26a that faces away from the interface 27. A partial region 30 of the surface 28, which is located within the reflective coating 29, is struck by the EUV radiation 16 of the projection system 10 and forms an optically utilized partial region of the reflective coating 29. The reflective coating 29 may comprise, for example, a plurality of layer pairs made of materials with different real parts of the refractive index, the layers possibly being formed from Si and Mo, for example, in the case of a wavelength of the EUV radiation 16 of 13.5 nm. The surface 28 of the first partial body 26a is represented as a planar surface area in FIG. 2, although it may also have a curvature.

In the example shown in FIG. 2, a plurality of cooling channels 31, which run below the surface 28 to which the reflective coating 29 is applied, is formed in the substrate 25 in the region of the interface 27. In the example shown in FIG. 2, there are approximately twenty cooling channels 31, which extend below the surface 28 between a distributor 32 and a collector 33, which are on opposite sides of the optically utilizable partial region 30 of the reflective coating 29. In the example shown in FIG. 2, the cooling channels 31 are aligned parallel to one another. In the example of FIG. 2, the distributor 32 has a distributor chamber 32a, which connects the plurality of cooling channels 31 to a common coolant inlet 34, which forms an opening in the second partial body 29b. Correspondingly, the collector 33 forms a collecting chamber, which connects the plurality of cooling channels 31 to a common coolant outlet 35, which is likewise in the form of an opening in the second partial body 29b.

As can be seen in FIG. 2, the distributor chamber 32a widens in funnel-shaped fashion from the coolant inlet 34 to the ends of the cooling channels 31, which open into the distributor chamber 32a. Correspondingly, the collecting chamber 33a narrows in funnel-shaped fashion from the ends of the cooling channels 33 to the coolant outlet 35. The distributor chamber 32a and the collecting chamber 33a extend along the interface 27 and are formed as flatly as possible in the thickness direction of the substrate 25. In the example shown in FIG. 2, the distributor chamber 32a and the collecting chamber 33a extend both into the first partial body 26a and into the second partial body 26b. The distributor chamber 32a and the collecting chamber 33a have a substantially triangular geometry that is optimized in terms of flow, in order as far as possible to achieve a uniform distribution of the coolant among all the coolant channels 31 and as low as possible a dynamic excitation owing to the flow of the cooling water.

To feed the coolant to the coolant inlet 34 and to discharge the coolant from the coolant outlet 35, the projection exposure apparatus 1 comprises a cooling device 36, which is represented schematically in FIG. 1. In the example shown, the cooling device 36 serves to feed a coolant in the form of cooling water to the cooling channels 31 or to the mirror M4, and to this end comprises a feed line, not depicted here, which is connected to the coolant inlet 34 in fluid-tight fashion. The cooling device 36 also comprises a discharge line, not depicted here, in order to discharge the cooling water from the coolant outlet 35. For cooling purposes, the other mirrors M1-M3, M5, M6 of the projection system 10 may also be connected to the cooling device 36 or optionally to further cooling devices provided to this end.

The pressure of the cooling water flowing through the distributor chamber 32a or through the collecting chamber 33a may lead to bulging of the substrate 25, the result of which is a change in the geometry of the surface 28. Owing to the relative proximity of the distributor chamber 32a and/or the collecting chamber 33a to the optically utilized partial region 30 of the surface 28, in this way undesired deformation of the optically utilized partial region 30 can occur.

In order to reduce the effects of the bulging of the distributor chamber 32a and/or the collecting chamber 33a on the optically utilized partial region 30 of the reflective coating 29, in the case of the mirror M4 shown in FIGS. 3A-3B the distributor 32, or the distributor chamber 32a, and the collector 33, or the collecting chamber 33a, extend from the interface 27 only into the second partial body 26a of the substrate 25. It is possible for the distributor chamber 32a and/or the collecting chamber 32b to extend from the interface 27 into the first partial body 26a a little, in order to connect the cooling channels 31 to one another at their ends additionally also in the first partial body 26a. As can be seen in FIG. 3A, the distributor chamber 32a extends from the coolant inlet 34, which is formed on the underside of the substrate 25, to the interface 27. Correspondingly, the collecting chamber 33a, not depicted in FIGS. 3A-3B, also extends from the interface 27 to the coolant outlet 35, which is likewise formed on the underside of the substrate 25.

The distributor chamber 32a, more precisely a center plane M of the distributor chamber 32a, in this respect is aligned parallel to the thickness direction Z of the substrate 25. As can be seen in the partial section of FIG. 3A, the center plane M runs in the Z direction and in the X direction. The distributor chamber 32a is substantially mirror-symmetrical in relation to the center plane M. The center plane M also runs through the coolant inlet 34, which forms an opening in the underside of the second partial body 26b. In this case, the underside of the second partial body 26b extends perpendicularly to the thickness direction in an XY plane of an XYZ coordinate system. This considerably reduces the surface area of the distributor chamber 32a that can bulge owing to the fluid pressure parallel to the surface 28 or to the optically utilized partial region 30 of the surface 28 of the mirror M4. Therefore, tilting the distributor 32 and/or the collector 33 into the second partial body 26b makes it possible to reduce deformations of the optically utilized partial region 30 on the surface 28 of the mirror M4.

It is not mandatory for the distributor chamber 32a to run in the thickness direction Z of the substrate 25; rather, the distributor chamber 32a, more precisely its center plane M, may also be aligned at an angle α to the thickness direction Z which generally should be no more than approximately 30°. The collector 33 which can be seen in the partial section of FIG. 3A, or the collecting chamber 33a, in the example shown has an identical structure to the distributor 32, or the distributor chamber 33a, on that side of the optically active partial region 30 of the surface 28 of the substrate 25 that is situated opposite in the Y direction. However, a structurally identical design is not mandatory. It may be advantageous, for example for flow-related reasons, if the distributor 32 and/or the distributor chamber 32a and the collector 33 and/or the collecting chamber 33a to have a different geometry.

As can be seen for example in FIG. 3B, both the distributor chamber 32a and the collecting chamber 33a run below, in the Z direction, a partial region 37 of the surface 28 that is not covered by the reflective coating 29, for example also not below the optically utilized partial region 30 of the surface 28. This enlarges the spacing of the triangular surface area, visible in FIG. 3A, that is subjected to pressure, is formed within the distributor chamber 32a and can bulge, from the optically effective partial region 30 of the surface 28. Such an arrangement is fundamentally also possible in the case of the mirror M4 shown in FIG. 2, for which the distributor chamber 32a and the collecting chamber 33a extend along the interface 27 between the two partial bodies 26a, b, since the structural space in the lateral direction in the case of the mirror M4 shown in FIG. 2 is sufficient for this.

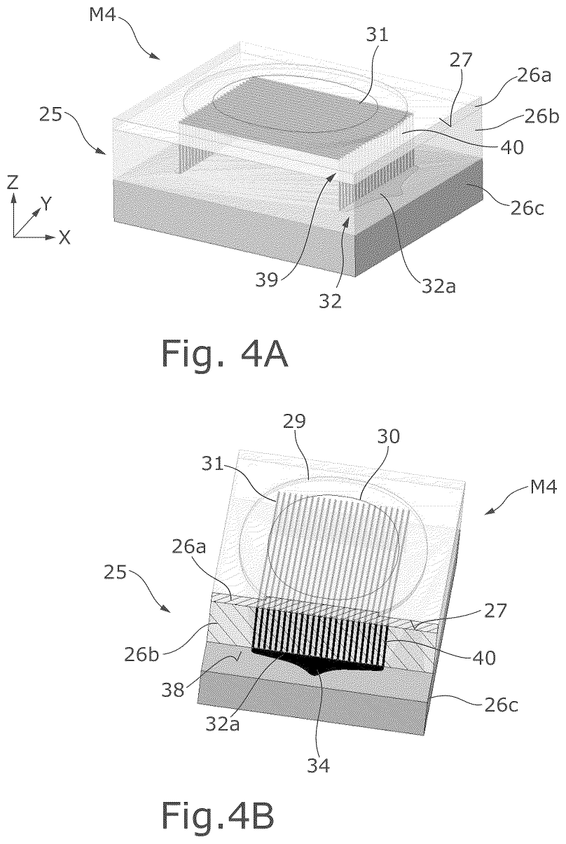

In the case of the mirror M4 illustrated in FIGS. 4A-4B, the substrate 25 has a third partial body 26c in addition to the first and the second partial body 26a, b. The third partial body 26c is connected to or put together with the second partial body 26b at a further interface 38 and is likewise made of ULE®. The connection can be formed like the connection described above at the interface 27 between the first and the second partial body 26a, b. The collector 32 shown in FIGS. 4A-4B has a portion 39 which is connected to the interface 27 between the first and the second partial body 26a, b and extends from the interface 27 into the second partial body 26b of the substrate 25. Connecting channels 40, which extend in the thickness direction Z of the substrate 25, are formed in that portion 39 of the distributor 32 that is connected to the interface 27.

As in the case of the example described in FIGS. 3A-3B, it is also not mandatory in FIGS. 4A-4B for the connecting channels 40 to be aligned in the thickness direction Z of the substrate 25; rather, as in FIGS. 3A-3B, an alignment of the connecting channels 40 at an angle α of typically no more than 30° to the thickness direction Z is possible. It can also be advantageous if the angle α, at which the connecting channels 40 are aligned in relation to the thickness direction Z of the substrate 25, varies in the substrate 25.

In the example shown in FIGS. 4A-4B, a respective connecting channel 40 is connected to exactly one cooling channel 31 and downwardly continues the latter into the second partial body 26b. In other words, a respective cooling channel 31 is deflected from an alignment parallel to the interface 27 into the second partial body 26b by a connecting channel 40 which is assigned to it. In the example shown in FIGS. 4A-4B, the connecting channels 40 run below a partial region of the surface 28 that is not covered by the optically active partial region 30.

In the example shown in FIGS. 4A-4B, the coolant is distributed among the individual cooling channels 31 via a distributor chamber 32a, which is connected to the connecting channels 40. The connecting channels 40 open into the distributor chamber 32a, which connects the connecting channels 40 to the coolant inlet 34. In the example shown in FIGS. 4A-4B, the distributor chamber 32a extends along the further interface 38 between the second and the third partial body 26b, c of the substrate 25. In the example shown, the further interface 38 extends in a plane parallel to the base area of the third partial body 26c, although such an alignment is not mandatory. The coolant inlet 34 forms an opening which runs through the third partial body 26c and ends on the underside of the substrate 25. As an alternative, the coolant inlet 34 may be formed in the second partial body 26b. In the case of the mirror M4 shown in FIGS. 4A-4B, the surface area of the funnel-shaped distributor chamber 32a may be spaced apart from the surface 28 of the substrate 25 to a greater extent than is the case for the mirror M4 shown in FIGS. 3A-3B. The collector 33 has a similar form to the distributor 32.

In the case of the mirror M4 shown in FIGS. 4A-4B, a further interface 38 is used to connect the connecting channels 40, which run in the Z direction, to the coolant inlet 34.

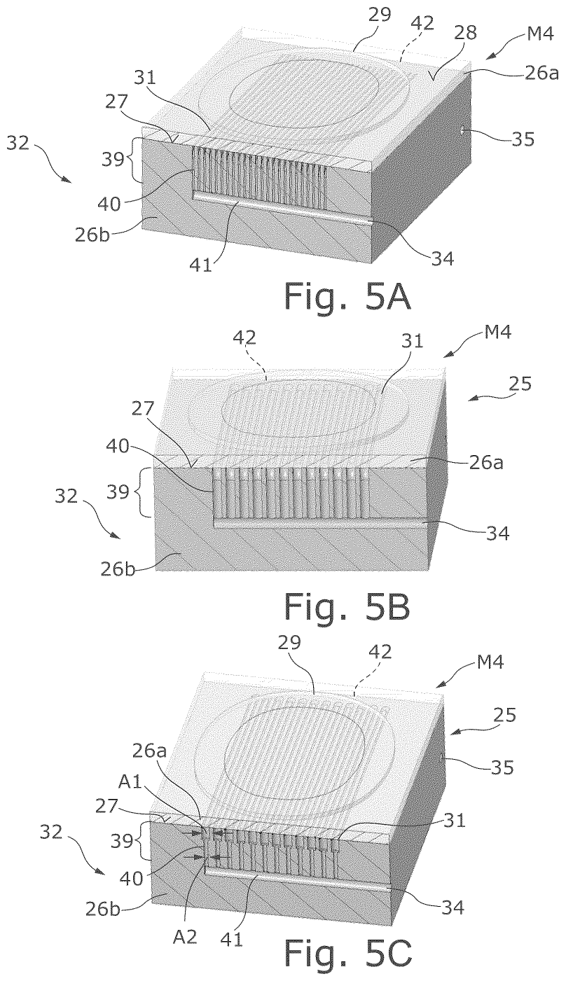

In the case of the mirror M4 shown in FIGS. 5A-5C, the connecting channels 40 of the distributor 32 are connected to a common inlet channel 41. In the case of the mirror M4 shown in FIGS. 5A-5C, the inlet channel 41 is in the form of a transverse bore, or blind bore, in the second partial body 26b. The connecting channels 40 branch off from the common inlet channel 41 upward (in the Z direction), toward the surface 28 of the first partial body 26a. In the case of the example shown in FIGS. 5A-5C, the coolant inlet 41 forms an opening of the inlet channel 41 which is formed on a side face of the second partial body 26b of the substrate 25. The collector 33 is structurally identical to the distributor 32 and likewise has connecting channels 40 which open into a common outlet channel 42, which in FIGS. 5A-5C is concealed by the substrate 25 and is connected to the coolant outlet 35.

In the case of both the mirror M4 shown in FIGS. 4A-4B and that shown in FIGS. 5A-5C, the connecting channels 40 are in the form of bores in the second partial body 26b of the substrate 25. For the case in which, as in FIGS. 4A-4B and FIGS. 5A-5C, there are many connecting channels 40 which extend relatively deeply into the second partial body 26b, there is a considerable manufacturing risk that, during the boring operation, the second partial body 26b is possibly damaged or in the worst case destroyed when the connecting channels 40 are being produced.

In order to reduce this risk, in the example shown in FIG. 5B a respective connecting channel 40 is connected not to one but to two respective adjacent cooling channels 31. In this way, the connecting channels 40 can be manufactured with a larger cross section than is the case in the example shown in FIG. 5A. If appropriate, it is also possible for more than two, generally adjacent cooling channels 31 to be connected to one and the same connecting channel 40, in order to further reduce the manufacturing risk.

For the case in which the cross-sectional areas of the connecting channels 40 that are subjected to pressure are too large and/or the ribs between the connecting channels 40 in the substrate 25 are too small, it is favorable for the connecting channels 40 to be in the form of stepped bores, as illustrated in FIG. 5C. In this case, the connecting channels 40 have, directly adjacent to the interface 27, a first cross-sectional area A1 which is enough to connect a respective connecting channel 40 to two respective cooling channels 31. At a step, the first cross-sectional area A1 is reduced to a second, smaller cross-sectional area A2, as a result of which the spacing between two respective adjacent connecting channels increases. A respective connecting channel 40 may possibly also have two or more steps in order to reduce the cross-sectional area A1, A2, etc. from the interface 27 to the inlet channel 41. A reduction in the cross-sectional area A1, A2, etc. of a respective connecting channel 40 from the interface 27 to the distributor chamber 32a is also possible in the case of the mirror M4 shown in FIGS. 4A-4B.

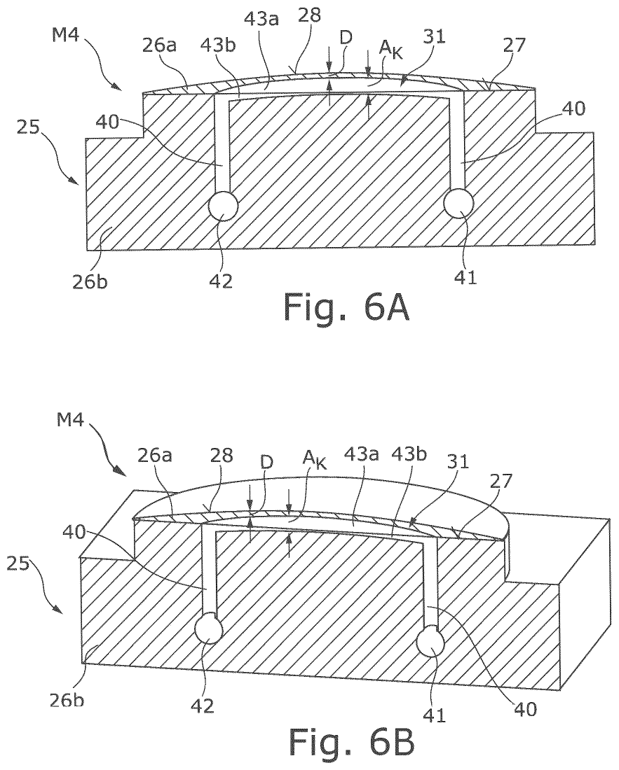

FIGS. 6A-6B show a section through a substrate 25 of a mirror M4, in the case of which the distributor 32 and the collector 33 are designed as in FIG. 5A. In the case of the mirror M4 of FIGS. 6a, b, a respective connecting channel 40 of the distributor is connected to a common inlet channel 41 and branches off from the latter toward the +surface 28 of the first partial body 26a. The inlet channel 41 is connected to a coolant inlet, which is not depicted in FIGS. 6A-6B. The collector is structurally identical and has connecting channels 40 to the cooling channels 31 which open into a common outlet channel 42 connected to a coolant outlet, which is not depicted in FIGS. 6A-6B.

By contrast to the mirror M4 shown in FIG. 5A, the cooling channel 31 in the case of the example shown in FIGS. 6a, b has a cross section which is divided between the two partial bodies 26a, b, that is to say the planar interface 27 between the two partial bodies 26a, b runs through the cross section, or the cross-sectional area AK, of the cooling channel 31. The cooling channel 31 is thus composed of a first groove-shaped depression 43a, formed in the first partial body 26a, and a second groove-shaped depression 43b, formed in the second partial body 26b. Such a division of the cross section of the cooling channel 31 between the two partial bodies 26a, b is favorable for example when the surface 28 of the substrate 25 is curved, as is the case in FIGS. 6A-6B.

In this case as well, the spacing D of the cooling channel 31 from the curved surface 28 should be substantially constant over the length of the cooling channel 31. This involves the cooling channel 31 being curved, with the curvature of the cooling channel 31 following or corresponding to the curvature of the surface 28. Since the interface 27 between the two partial bodies 26a, b is planar, a cooling channel 31 with a cross-sectional area AK that is constant over the length of the cooling channel 31 can only be realized in this case if not only a first, curved groove-shaped depression 43a is formed in the first partial body 26a but also a second, curved groove-shaped depression 43b is formed in the second partial body 26b, as shown in FIGS. 6A-6B. It goes without saying that the cooling channels 31 of the mirror M4 that was described above in connection with FIG. 2, FIGS. 3A-3B, FIGS. 4A-4B and FIGS. 5B-5C may also have corresponding designs, that is to say that their cross section can be divided between the two partial bodies 26a, b.

Instead of a single distributor 32 and/or a single collector 33, it is optionally possible for multiple distributors 32 and/or collectors 33 to also be formed in the substrate 25 in order to connect a respective plurality of cooling channels 31, which run below the surface 28 with the reflective coating 29, to a respective coolant inlet 34 and to a respective coolant outlet 35, respectively. However, it can be favorable if only a single coolant inlet 34 and only a single coolant outlet 35 are formed on the substrate 25.

Instead of a reflective coating 29 for EUV radiation 16, a reflective coating for radiation in a different wavelength range, for example for the DUV wavelength range, may also be applied to the optical element described above. As a rule, there are less stringent desired thermal expansion properties for the substrate 25 for such a reflective optical element, and so use can be made of different substrate materials to those described above, for example conventional fused silica.

What is claimed is:

1. An optical element configured to reflect radiation, the optical element comprising:
a substrate comprising first and second partial bodies joined at an interface;
a reflective coating supported by a surface of the first partial bodies;
a plurality of cooling channels in the substrate in a region of the interface below the surface supporting the reflective coating;
a distributor in the substrate and configured to connect a coolant inlet to the plurality of cooling channels; and
a collector in the substrate and configured to connect the plurality of cooling channels to a coolant outlet,
wherein:
at least one member selected from the group consisting of the distributor and the collector extends, proceeding from the interface, further into the second partial body of the substrate than into the first partial body of the substrate; and
a cross section of a respective cooling channel is divided between the first partial body and the second partial body.

2. The optical element of claim 1, wherein the at least one member, in the second partial body at least in a portion proceeding from the interface, is aligned at an angle of at most 30° relative to a thickness direction of the substrate.

3. The optical element of claim 1, wherein the at least one member, in the second partial body at least in a portion proceeding from the interface, is below a partial region of the surface that is not covered by the reflective coating.

4. The optical element of claim 1, wherein the distributor comprises a distributor chamber which widens from the coolant inlet, and/or wherein the collector comprises a collecting chamber which tapers toward the coolant outlet.

5. The optical element of claim 4, wherein the distributor chamber extends from the coolant inlet to the interface, and/or wherein the collecting chamber extends from the interface to the coolant outlet.

6. The optical element of claim 1, wherein the at least one member comprises a portion which proceeds from the interface and comprises connecting channels configured to connect at least one cooling channel to the coolant inlet or to the coolant outlet.

7. The optical element of claim 6, wherein a connecting channel is connected to at least two cooling channels.

8. The optical element of claim 6, wherein a cross section of a connecting channel decreases from the interface.

9. The optical element of claim 6, wherein the distributor chamber is connected to the portion of the distributor having the connecting channels of the distributor, and/or wherein the collecting chamber is connected to the portion of the collector that has the connecting channels of the collector.

10. The optical element of claim 9, wherein at least one chamber selected from the group consisting of the distributor chamber and the collecting chamber extends along a further interface between the second partial body and a third partial body of the substrate that is joined with the second partial body at the further interface.

11. The optical element of claim 6, wherein the connecting channels of the distributor open into a common inlet channel which is connected to the coolant inlet, and/or wherein the connecting channels of the collector open into a common outlet channel which is connected to the coolant outlet.

12. The optical element of claim 1, wherein at least one inlet selected from the group consisting of the coolant inlet and the coolant outlet is in at least one partial body selected from the group consisting of the second partial body and a third partial body of the substrate.

13. The optical element of claim 1, wherein the surface supporting the reflective coating is curved, and/or wherein the cooling channel is curved.

14. The optical element of claim 13, wherein the cooling channel is a constant spacing from the surface supporting the reflective coating.

15. The optical element of claim 13, wherein the at least one member comprises a portion which proceeds from the interface and comprises connecting channels configured to connect at least one cooling channel to the coolant inlet or to the coolant outlet.

16. The optical element of claim 1, wherein the radiation comprises EUV radiation.

17. An optical arrangement, comprising:
an optical element according to claim 1; and
a cooling device configured to provide a coolant to the plurality of cooling channels.

18. The optical arrangement of claim 17, wherein the radiation comprises EUV radiation.

19. An apparatus, comprising:
an optical arrangement, comprising:
an optical element according to claim 1; and
a cooling device configured to provide a coolant to the plurality of cooling channels,
wherein the apparatus is a lithography projection exposure apparatus.

20. The apparatus of claim 19, wherein the radiation comprises EUV radiation.
